(19) United States
(12) Patent Application Publication
(10) Pub. No.: US 2024/0179999 A1
(43) Pub. Date: May 30, 2024

(54) DISPLAY DEVICE AND METHOD OF MANUFACTURING THE SAME

(71) Applicant: Samsung Display Co., LTD., Yongin-si (KR)

(72) Inventor: JONGSUK LEE, Yongin-si (KR)

(21) Appl. No.: 18/226,485

(22) Filed: Jul. 26, 2023

(30) Foreign Application Priority Data
Nov. 30, 2022 (KR) 10-2022-0165245

(51) Int. Cl. H10K 59/80; H10K 59/12

(52) U.S. Cl. CPC H10K 59/873; H10K 59/1201

(57) ABSTRACT

A display device includes: a display panel including a front area, side areas disposed around the front area, and corner areas respectively disposed between two adjacent side areas among the side areas, where the display panel includes a flat surface in the front area and a curved surface in the side areas and the corner areas, and a first resin layer disposed under the display panel and partially overlapping the corner areas.

This application claims priority to Korean Patent Application No. 10-2022-0165245, filed on Nov. 30, 2022, and all the benefits accruing therefrom under 35 U.S.C. § 119, the content of which in its entirety is herein incorporated by reference.

### BACKGROUND

### 1. Field

Embodiments relate to a display device. More particularly, embodiments relate to a display device including a curved surface having improved display quality.

### 2. Description of the Related Art

A display device may include a window capable of transmitting light, a display panel positioned under the window to emit light, and a protective film attached to a lower portion of the display panel to protect the display panel. In the past, a display panel having only a flat surface had been used, but recently, a display panel including various curved surfaces has been used. Typically, such a display device is manufactured by attaching the display panel to a lower portion of the window.

### SUMMARY

A display panel of a display device may include a plurality of curved surfaces and corner areas (e.g., located adjacent to an edge of the display panel) located between two adjacent curved surfaces among the plurality of curved surfaces. In such a display device, cracks, buckling, or wrinkling may occur when the corner areas of the display panel is attached to the window. Accordingly, display quality of the display device may be deteriorated.

Embodiments provide a display device with improved display quality.

Embodiments provide a method of manufacturing the display device.

A display device according to an embodiment includes a display panel including a front area, side areas disposed around the front area, and corner areas respectively disposed between two adjacent side areas among the side areas, where the display panel includes a flat surface in the front area and a curved surface in the side areas and the corner areas, and a first resin layer disposed under the display panel and partially overlapping the corner areas.

In an embodiment, the first resin layer may include a first surface disposed along a portion of an edge of the display device in a plan view.

In an embodiment, the first resin layer may have a shape surrounded by the first surface, a second surface extending from the first surface in a first direction, a third surface extending from the first surface in a second direction crossing the first direction, and a fourth surface connecting the second surface and the third surface in a plan view.

In an embodiment, the fourth surface may be a curved surface.

In an embodiment, the display device may further include a second resin layer disposed under the first resin layer.

In an embodiment, the display device may further include a protective film disposed between the first resin layer and the display panel.

In an embodiment, the display device may further include a protective film disposed between the first resin layer and the display panel.

In an embodiment, the display device may further include a second adhesive layer disposed on the display panel and a cover window disposed on the second adhesive layer.

In an embodiment, the first resin layer may have a modulus of about 0.2 megapascal (MPa) or greater and about 1 gigapascal (GPa) or less.

In an embodiment, the first resin layer may have a viscosity of about 300 centiPoise (cps) or greater and about 1,000,000 cps or less.

In an embodiment, a thickness of the first resin layer may be about 20 micrometers (μm) or greater and about 500 μm or less.

A method of manufacturing a display device according to an embodiment includes preparing a display panel including a front area, side areas disposed around the front area, and corner areas respectively disposed between two adjacent side areas among the side areas, attaching a guide film, in which a first cutout portion partially overlapping the corner areas is defined, on a rear surface of the display panel, providing a resin layer on a portion of a rear surface of the display panel exposed by the first cutout portion, disposing a cover window on a front surface of the display panel, and removing the guide film.

In an embodiment, the attaching the guide film on the rear surface of the display panel may include providing an adhesive layer, in which a second cutout portion overlapping the first cutout portion is defined, on the rear surface of the display panel, and attaching the guide film to a rear surface of the adhesive layer.

In an embodiment, a thickness of the resin layer may be less than or equal to a sum of a thickness of the adhesive layer and a thickness of the guide film.

In an embodiment, the providing the resin layer on the portion of the rear surface of the display panel exposed by the first cutout portion may include applying a preliminary resin layer on the rear surface of the display panel exposed by the first cutout portion, and curing the preliminary resin layer.

A method of manufacturing a display device according to an embodiment includes preparing a display panel including a front area, side areas disposed around the front area, and corner areas respectively disposed between two adjacent side areas among the side areas, providing a resin layer partially overlapping the corner areas on a rear surface of the display panel, attaching a guide film to a rear surface of the resin layer, disposing a cover window on a front surface of the display panel, and removing the guide film.

In an embodiment, the providing the resin layer on the rear surface of the display panel may include applying a preliminary resin layer on the rear surface of the display panel and curing the preliminary resin layer.

In an embodiment, the attaching the guide film to the rear surface of the resin layer may include providing an adhesive layer on the rear surface of the display panel except for an area where the resin layer is provided and attaching the guide film on the rear surface of the adhesive layer and the resin layer.

In an embodiment, a thickness of the resin layer may be less than or equal to a thickness of the adhesive layer.

In an embodiment, the removing the guide film may include removing the guide film except for a portion thereof overlapping the resin layer.

A display device according to embodiments of the invention includes a display panel including a front area, side areas disposed around the front area, and corner areas respectively disposed between two adjacent side areas among the side areas, where the display panel includes a flat surface in the front area and a curved surface in the side areas and the corner areas, and a first resin layer disposed under the display panel and partially overlapping the corner areas.

In such embodiments, when a display panel containing corner areas having a certain amount of curvature is attached to a lower portion of the window, buckling or cracks may not occur in the corner areas of the display device. In such embodiments, even after a bonding process between the display panel and the window, buckling or cracks may not occur in the corner areas of the display panel when an auto clave process for removing air bubbles present in the adhesive layer proceeds.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating a display device according to an embodiment.

FIG. 2 is a view schematically illustrating a stacked structure of the display device of FIG. 1.

FIG. 3 is a perspective view illustrating the display panel of FIG. 2.

FIG. 4 is a cross-sectional view illustrating a display unit included in the display panel of FIG. 3.

FIG. 5 is a plan view illustrating the display device of FIG. 1.

FIG. 6 is a cross-sectional view of the display device of FIG. 1 taken along line I-I′.

FIGS. 7 to 9 are enlarged views of part A of FIG. 5.

FIG. 10 is a perspective view illustrating a guide film according to an embodiment.

FIGS. 11 to 19 are views illustrating a method of manufacturing a display device according to an embodiment.

FIGS. 20 to 24 are views illustrating a method of manufacturing a display device according to an alternative embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, display devices in accordance with embodiments will be described in more detail with reference to the accompanying drawings. The same reference numerals are used for the same components in the drawings, and redundant descriptions of the same components will be omitted.

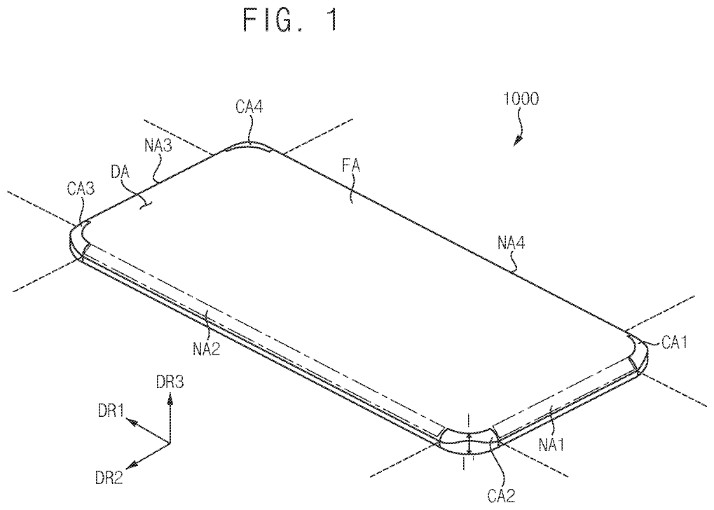

FIG. 1 is a perspective view illustrating a display device according to an embodiment.

Referring to FIG. 1, an embodiment of a display device 1000 may include a display area DA and a non-display area (not shown). The display area DA is an area capable of displaying an image by emitting light. The display area DA may include a front area FA, side areas NA1, NA2, NA3, and NA4, and corner areas CA1, CA2, CA3, and CA4 located between two adjacent side areas among the side areas NA1, NA2, NA3, and NA4, respectively.

In an embodiment, a first corner area CA1 may be disposed between a fourth side area NA4 and a first side area NA1. In addition, a second corner area CA2 may be disposed between the first side area NA1 and a second side area NA2. In addition, a third corner area CA3 may be disposed between the second side area NA2 and a third side area NA3. In addition, a fourth corner area CA4 may be disposed between the third side area NA3 and the fourth side area NA4.

The display device 1000 may have a flat surface in the front area FA, and may have curved surfaces in side areas NA1, NA2, NA3, and NA4 and corner areas CA1, CA2, CA3, and CA4.

The non-display area may be an area that does not emit light and may include a driving unit for driving the display area DA. In an embodiment, for example, the driving unit may include a data driving unit, a gate driving unit, or the like.

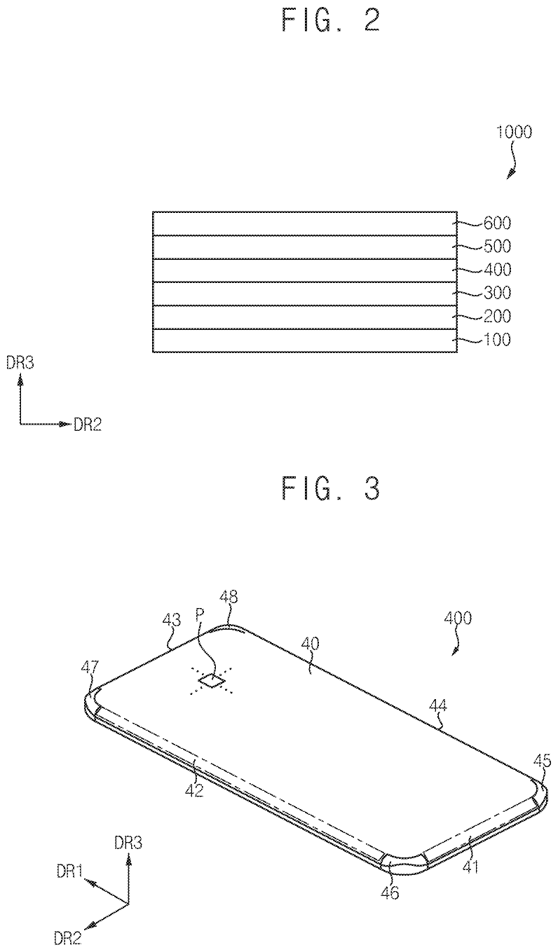

FIG. 2 is a view schematically illustrating a stacked structure of the display device of FIG. 1.

Referring to FIGS. 1 and 2, in an embodiment, the display area DA of the display device 1000 may include a protective film 200 disposed on a first resin layer 100, a first adhesive layer 300 disposed on the protective film 200, a display panel 400 disposed on the first adhesive layer 300, a second adhesive layer 500 disposed on the display panel 400, and a cover window 600 disposed on the second adhesive layer 500.

The cover window 600 may transmit light emitted from the display panel 400. The cover window 600 may include an insulating material such as transparent plastic or glass. The cover window 600 may be attached to the display panel 400 through the second adhesive layer 500. The cover window 600 may include curved surfaces in some areas (i.e., areas corresponding to side areas NA1, NA2, NA3, and NA4 or corner areas CA1, CA2, CA3, and CA4).

The second adhesive layer 500 may be disposed under the cover window 600. The second adhesive layer 500 may include an optical clear adhesive (“OCA”), an optical clear resin (“OCR”), or a pressure sensitive adhesive (“PSA”). The second adhesive layer 500 may transmit light. The second adhesive layer 500 may be disposed below the cover window 600 to provide an adhesive force to the cover window 600. The second adhesive layer 500 may include curved surfaces in some areas (i.e., areas corresponding to side areas NA1, NA2, NA3, and NA4 or corner areas CA1, CA2, CA3, and CA4).

The display panel 400 may be disposed under the second adhesive layer 500. The display panel 400 may include a plurality of display units (e.g., a display unit P of FIG. 3). Each of the plurality of display units may emit light. The display panel 400 may include curved surfaces in some areas (i.e., areas corresponding to side areas NA1, NA2, NA3, and NA4 or corner areas CA1, CA2, CA3, and CA4).

The first adhesive layer 300 may be disposed under the display panel 400. The first adhesive layer 300 may include OCA, OCR, or PSA. The first adhesive layer 300 may be disposed below the display panel 400 to provide an adhesive force to the display panel 400. The first adhesive layer 300 may include curved surfaces in some areas (i.e., areas corresponding to side areas NA1, NA2, NA3, and NA4 or corner areas CA1, CA2, CA3, and CA4).

The protective film 200 may be disposed under the first adhesive layer 300. The protective film 200 may protect a lower surface of the display panel 400. The protective film 200 may include curved surfaces in some areas (i.e., side areas NA1, NA2, NA3, and NA4 or corner areas CA1, CA2, CA3, and CA4).

The first resin layer 100 may be disposed under the protective film 200. The first resin layer 100 may include a cured resin. In an embodiment, for example, the cured resin may include an acrylic resin, an epoxy resin, a silicon resin, or the like. These materials may be used alone or in combination with each other. However, the invention is not limited thereto, and the cured resin may include other kinds of resins.

In describing the display device according to an embodiment of the disclosure, a first direction DR1 and a second direction DR2 crossing the first direction DR1 may be defined. In addition, a third direction DR3 perpendicular to a plane defined by the first direction DR1 and the second direction DR2 may be defined.

FIG. 3 is a perspective view illustrating the display panel of FIG. 2.

Referring to FIGS. 1 and 3, an embodiment of the display panel 400 may include a panel front part 40 in a portion overlapping the front area FA of the display device 1000. The panel front part 40 may be on a plane defined by the first direction DR1 and the second direction DR2. That is, the panel front part 40 may be perpendicular to the third direction DR3. The third direction DR3 may be a thickness direction of the display panel 400.

The display panel 400 may include a first panel side part 41 in a portion overlapping the first side area NA1 of the display device 1000. The first panel side part 41 may be adjacent to the panel front part 40 in a direction opposite to the first direction DR1. The first panel side part 41 may be a portion bent from the panel front part 40.

The display panel 400 may include a second panel side part 42 in a portion overlapping the second side area NA2 of the display device 1000. The second panel side part 42 may be adjacent to the panel front part 40 in the second direction DR2. The second panel side part 42 may be a portion bent from the panel front part 40.

The display panel 400 may include a third panel side part 43 in a portion overlapping the third side area NA3 of the display device 1000. The third panel side part 43 may be adjacent to the panel front part 40 in the first direction DR1. The third panel side part 43 may be a portion bent from the panel front part 40.

The display panel 400 may include a fourth panel side part 44 in a portion overlapping the fourth side area NA4 of the display device 1000. The fourth panel side part 44 may be adjacent to the panel front part 40 in a direction opposite to the second direction DR2. The fourth panel side part 44 may be a portion bent from the panel front part 40.

The first to fourth panel side parts 41, 42, 43, and 44 may be bent with a predetermined curvature. In an embodiment, the first to fourth panel side parts 41, 42, 43, and 44 may have a same curvature as each other. However, the disclosure is not limited thereto. In an embodiment, for example, the first and third panel side parts 41 and 43 may have a same curvature as each other, the second and fourth panel side parts 42 and 44 may have a same curvature as each other, and the first and third panel side parts 41 and 43 may have a different curvature from that of the second and fourth panel side parts 42 and 44.

The display panel 400 may include a first panel corner part 45 in a portion overlapping the first corner area CAL of the display device 1000. The first panel corner part may be disposed between the first panel side part 41 and the fourth panel side part 44. The first panel corner part 45 may be bent as the first panel side part 41 and the fourth panel side part 44 are bent from the panel front part 40.

The display panel 400 may include a second panel corner part 46 in a portion overlapping the second corner area CA2 of the display device 1000. The second panel corner part 46 may be disposed between the first panel side part 41 and the second panel side part 42. The second panel corner part 46 may be bent as the first panel side part 41 and the second panel side part 42 are bent from the panel front part 40.

The display panel 400 may include a third panel corner part 47 in a portion overlapping the third corner area CA3 of the display device 1000. The third panel corner part 47 may be disposed between the second panel side part 42 and the third panel side part 43. The third panel corner part 47 may be bent as the second panel side part 42 and the third panel side part 43 are bent from the panel front part 40.

The display panel 400 may include a fourth panel corner part 48 in a portion overlapping the fourth corner area CA4 of the display device 1000. The fourth panel corner part 48 may be disposed between the third panel side part 43 and the fourth panel side part 44. The fourth panel corner part 48 may be bent as the third panel side part 43 and the fourth panel side part 44 are bent from the panel front part 40.

In an embodiment, each of the first to fourth panel corner parts 45, 46, 47, and 48 may have two or more curvatures. in such an embodiment, two or more curvatures may overlap in each of the first to fourth panel corner parts 45, 46, 47, and 48. The overlapping curvature may be defined as a curvature amount (or degree of curvature).

Features of the display panel 400 are described above with reference to FIG. 3, but it is not limited thereto, and the protective film 200, the first adhesive layer 300, the second adhesive layer 500, and the cover window 600 of FIG. 2 may also be configured as the display panel 400.

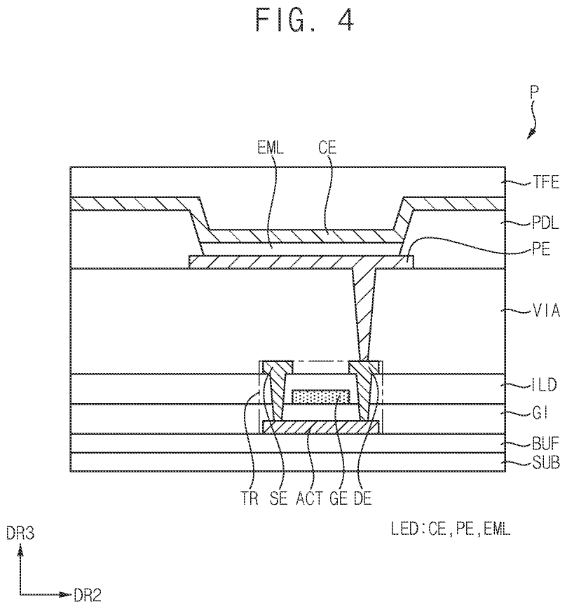

FIG. 4 is a cross-sectional view illustrating a display unit included in the display panel of FIG. 3.

Referring to FIG. 4, in an embodiment, the display unit (or a pixel unit) P may include a substrate SUB, a buffer layer BUF, a gate insulating layer GI, an interlayer insulating layer ILD, a via insulating layer VIA, an active layer ACT, a source electrode SE, a gate electrode GE, a drain electrode DE, a pixel electrode PE, a pixel defining layer PDL, a light emitting layer EML, a common electrode CE, and an encapsulating layer TFE.

The transistor TR may include the active layer ACT, the source electrode SE, the gate electrode GE, and the drain electrode DE.

A substrate SUB may include a transparent material or an opaque material. The substrate SUB may include or be formed of a transparent resin substrate. In an embodiment, for example, the transparent resin substrate may include a polyimide substrate. In such an embodiment, the polyimide substrate may include a first organic layer, a first barrier layer, a second organic layer, or the like.

Alternatively, the substrate SUB may include a quartz substrate, a synthetic quartz substrate, a calcium fluoride substrate, a fluorine-doped quartz substrate, a sodalime substrate, a non-alkali glass substrate, or the like. These materials may be used alone or in combination with each other.

A buffer layer BUF may be disposed on the substrate SUB. The buffer layer BUF may prevent metal atoms or impurities from diffusing from the substrate SUB to the transistor TR. In addition, the buffer layer BUF can improve the flatness of a surface of the substrate SUB when the surface of the substrate SUB is not uniform.

In an embodiment, for example, the buffer layer BUF may include an inorganic material such as silicon oxide, silicon nitride, silicon oxynitride, or the like. These materials may be used alone or in combination with each other.

An active layer ACT may be disposed on the buffer layer BUF. The active layer ACT may include a metal oxide semiconductor, an inorganic semiconductor (e.g., amorphous silicon, polysilicon), an organic semiconductor, or the like. These materials may be used alone or in combination with each other. The active layer ACT may include a source area, a drain area, and a channel area disposed between the source area and the drain area.

The metal oxide semiconductor may include a binary compound (ABₓ), a ternary compound (ABₓC_{y}), a tetragonal compound (ABₓCD_{z}), or the like, each including indium (In), zinc (Zn), gallium (Ga), tin (Sn), titanium (Ti), aluminum (Al), hafnium (Hf), zirconium (Zr), magnesium (Mg), or the like.

In an embodiment, for example, the metal oxide semiconductor may include zinc oxide (ZnOₓ), gallium oxide (GaOₓ), tin oxide (SnOₓ), indium oxide (InOₓ), indium gallium oxide (“IGO”), indium zinc oxide (“IZO”), indium tin oxide (“ITO”), indium zinc tin oxide (“IZTO”), or indium gallium zinc oxide (“IGZO”). These materials may be used alone or in combination with each other.

A gate insulating layer GI may be disposed on the buffer layer BUF. The gate insulating layer GI may sufficiently cover the active layer ACT, and may have a substantially flat upper surface without generating a step (or a step-like structure) around the active layer ACT. Alternatively, the gate insulating layer GI may cover the active layer ACT and may be disposed along a profile of the active layer ACT.

In an embodiment, for example, the gate insulating layer GI may include an inorganic material such as silicon oxide (SiOₓ), silicon nitride (SiNₓ), silicon carbide (SiCₓ), silicon oxynitride (SiOₓN_{y}), silicon oxycarbide (“SiOₓC_{y}”), or the like. These materials may be used alone or in combination with each other.

A gate electrode GE may be disposed on the gate insulating layer GI. The gate electrode GE may overlap the channel area of the active layer ACT.

The gate electrode GE may include a metal, an alloy metal nitride, a conductive metal oxide, a transparent conductive material, or the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or the like. Examples of the conductive metal oxide may include ITO, IZO, or the like. In addition, examples of the metal nitride may include aluminum nitride (AlNₓ), tungsten nitride (WNₓ), chromium nitride (CrNₓ), or the like. Each of these materials may be used alone or in combination with each other.

An interlayer insulating layer ILD may be disposed on the gate insulating layer GI. The interlayer insulating layer ILD may sufficiently cover the gate electrode GE, and may have a substantially flat upper surface without generating a step around the gate electrode GE. Alternatively, the interlayer insulating layer ILD may cover the gate electrode GE, and may be disposed along a profile of the gate electrode GE.

In an embodiment, for example, the interlayer insulating layer ILD may include an inorganic material such as silicon oxide, silicon nitride, silicon carbide, silicon oxynitride, silicon oxycarbide, or the like. These materials may be used alone or in combination with each other.

A source electrode SE may be disposed on the interlayer insulating layer ILD. The source electrode SE may be connected to the source area of the active layer ACT through a contact hole defined through the gate insulating layer GI and the interlayer insulating layer ILD.

A drain electrode DE may be disposed on the interlayer insulating layer ILD. The drain electrode DE may be connected to the drain area of the active layer ACT through a contact hole defined through the gate insulating layer GI and the interlayer insulating layer ILD.

In an embodiment, for example, the source electrode SE may include a metal, an alloy, a metal nitride, a conductive metal oxide, a transparent conductive material, or the like. These materials may be used alone or in combination with each other. The drain electrode DE may be formed through a same process as the source electrode SE and may include a same material as the source electrode SE.

A via insulating layer VIA may be disposed on the interlayer insulating layer ILD. The via insulating layer VIA may sufficiently cover the source electrode SE and the drain electrode DE. The via insulating layer VIA may include an organic material. In an embodiment, for example, the via insulating layer VIA may include an organic material such as phenolic resin, acrylic resin, polyimide resin, polyamide resin, siloxane resin, epoxy resin, or the like. These materials may be used alone or in combination with each other.

A pixel electrode PE may be disposed on the via insulating layer VIA. The pixel electrode PE may be connected to the drain electrode DE through a contact hole defined through the via insulating layer VIA.

The pixel electrode PE may include a metal, an alloy, a metal nitride, a conductive metal oxide, a transparent conductive material, or the like. These materials be used alone or in combination with each other. In an embodiment, the pixel electrode PE may have a stacked structure including ITO/Ag/ITO. In an embodiment, for example, the pixel electrode PE may operate as an anode.

A pixel defining layer PDL may be disposed on the via insulating layer VIA. The pixel defining layer PDL may cover both side portions of the pixel electrode PE. In addition, an opening exposing a portion of the upper surface of the pixel electrode PE may be defined in the pixel defining layer PDL.

In an embodiment, for example, the pixel defining layer PDL may include an inorganic material or an organic material. In an embodiment, the pixel defining layer PDL may include an organic material such as an epoxy resin, a siloxane resin, or the like. These materials may be used alone or in combination with each other. In an alternative embodiment, the pixel defining layer PDL may further include a light blocking material including a black pigment, a black dye, or the like.

A light emitting layer EML may be disposed on the pixel electrode PE. The light emitting layer EML may include an organic material that emits light of a predetermined color. In an embodiment, for example, the light emitting layer EML may include an organic material that emits red light. However, the disclosure is not limited thereto, and the light emitting layer EML may emit light of a different color from red light.

A common electrode CE may be disposed on the light emitting layer EML and the pixel defining layer PDL. The common electrode CE may include a metal, an alloy, a metal nitride, a conductive metal oxide, a transparent conductive material, or the like. These materials may be used alone or in combination with each other. The common electrode CE may operate as a cathode.

An encapsulation layer TFE may be disposed on the common electrode CE. The encapsulation layer TFE may prevent impurities and moisture from penetrating into the pixel electrode PE, the light emitting layer EML, and the common electrode CE from the outside. The encapsulation layer TFE may include at least one inorganic layer and at least one organic layer.

In an embodiment, for example, the inorganic layer may include silicon oxide, silicon nitride, silicon oxynitride, or the like. These materials may be used alone or in combination with each other. The organic layer may include a polymer cured product such as polyacrylate.

Although an embodiment of the display unit P is described with reference to FIG. 4, the display unit P is not limited to the structure shown in FIG. 4. That is, the display unit P may include all structures that receive an electrical signal and emit light having a luminance corresponding to the intensity of the electrical signal.

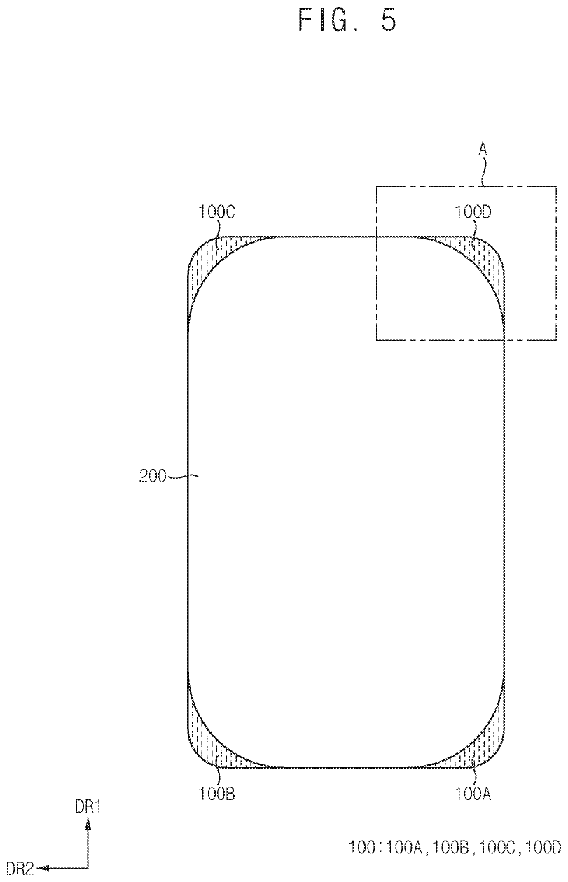

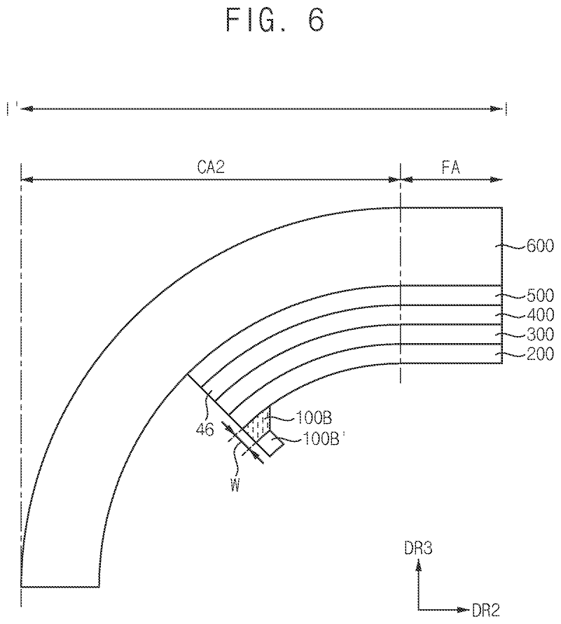

FIG. 5 is a plan view illustrating the display device of FIG. 1. FIG. 6 is a cross-sectional view of the display device of FIG. 1 taken along line I-I′. Specifically, FIG. is a plan view illustrating a protective film and a first resin layer disposed under the protective film of FIG. 2

Referring to FIGS. 1 and 5, the first resin layer 100 may include a first resin layer (hereinafter, will be referred to as “1-1 resin layer”) 100A, a second first resin layer (hereinafter, will be referred to as “1-2 resin layer”) 100B, a third first resin layer (hereinafter, will be referred to as “1-3 resin layer”) 100C, and a fourth first resin layer (hereinafter, will be referred to as “1-4 resin layer”) 100D.

The 1-1 resin layer 100A, the 1-2 resin layer 100B, the 1-3 resin layer 100C, and the 1-4 resin layer 100D may be disposed under the protective film 200. The 1-1 resin layer 100A may partially overlap the first corner area CA1 of the display device 1000. In addition, the 1-2 resin layer 100B may partially overlap the second corner area CA2. In addition, the 1-3 resin layer 100C may partially overlap the third corner area CA3. In addition, the 1-4 resin layer 100D may partially overlap the fourth corner area CA4.

Referring to FIGS. 1, 5, and 6, the first to fourth corner areas CA1, CA2, CA3, and CA4 of the display device 1000 may have a same structure as each other. For convenience of description, the second corner area CA2 will hereinafter be described with reference to FIG. 6, and any repetitive detailed descriptions of the remaining corner areas CA1, CA3, and CA4 will be omitted.

In an embodiment, for example, the 1-2 resin layer 100B may be the same as the remaining resin layers (that is, 1-1 resin layer 100A, 1-3 resin layer 100C, and 1-4 resin layer 100D). Referring to FIG. 6, the 1-2 resin layer 100B will be described, and descriptions of the remaining resin layers will be omitted.

As described above, the 1-2 resin layer 100B may be disposed under the protective film 200. In an embodiment, for example, the 1-2 resin layer 100B may partially overlap the second corner area CA2.

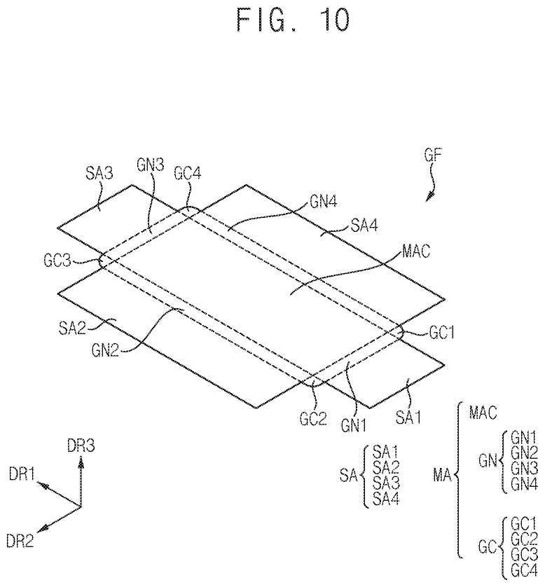

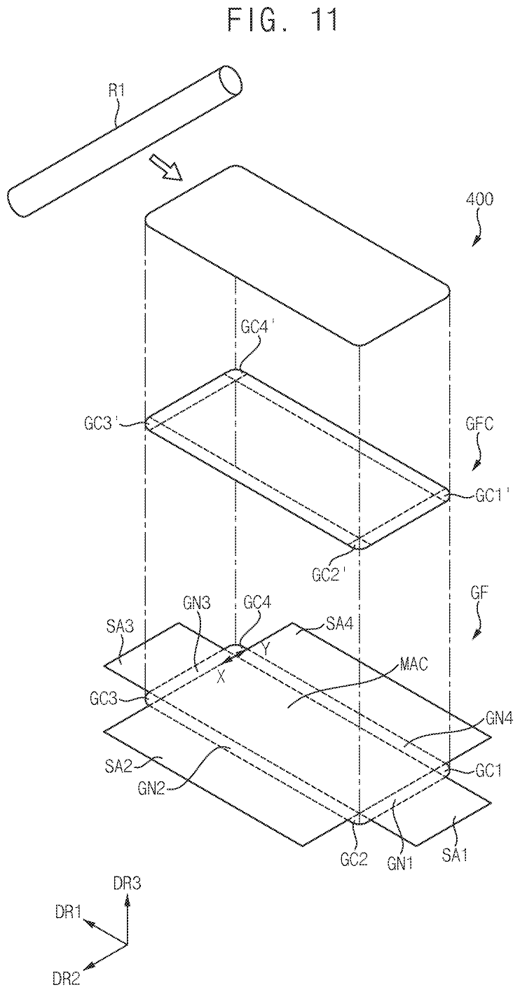

In an embodiment, a thickness of the 1-2 resin layer 100B may be about 20 micrometers (μm) or greater and about 500 μm or less. If the thickness of the 1-2 resin layer 100B is greater than about 500 μm, the thickness of the 1-2 resin layer 100B may be greater than a thickness of a guide film (for example, a guide film GF of FIG. 10) to be described later. In this case, as will be described with reference to FIGS. 11 to 19, the 1-2 resin layer 100B may overflow to a bottom surface of the guide film.

Compressive stress may be applied to the second panel corner part 46 when the above defined curvature amount of the second panel corner part 46 is large. Compressive stress may be applied to the second panel corner part 46 when the above defined curvature amount of the second panel corner part 46 is large. That is, the greater the curvature amount of the second panel corner part 46 during the lamination process, the greater the compressive stress acting on the second panel corner part 46.

If the thickness of the 1-2 resin layer 100B is less than about 20 μm, the compressive stress may not be sufficiently reduced such that buckling or cracks may occur in the corner areas CA1, CA2, CA3, and CA4 of the display device 1000.

In an embodiment, the 1-2 resin layer 100B may have a modulus about 0.2 megapascal (Mpa) or greater and about 1 gigapascal (Gpa) or less. If the modulus of the 1-2 resin layer 100B is less than about 0.2 Mpa, the deformation of the 1-2 resin layer 100B may be excessively free. In this case, it may be difficult for the 1-2 resin layer 100B to support the display panel 400 or the like.

On the other hand, if the modulus of the 1-2 resin layer 100B is greater than about 1 Gpa, the 1-2 resin layer 100B may not be effectively deformed. In this case, when compressive stress is applied to the 1-2 resin layer 100B, the 1-2 resin layer 100B may be distorted and wrinkles may occur.

In an embodiment, the 1-2 resin layer 100B may have a viscosity of about 300 centiPoise (cps) or greater and about 1,000,000 cps or less.

If the viscosity of the 1-2 resin layer 100B is less than about 300 cps, a shape of the 1-2 resin layer 100B may not be maintained such that the 1-2 resin layer 100B may not effectively support the display panel 400 or the like.

On the other hand, if the viscosity of the 1-2 resin layer 100B is greater than about 1,000,000 cps, there may be a limit in supplying the 1-2 resin layer 100B through a dispenser or the like.

In an embodiment, a second resin layer (not shown) may be disposed under the first resin layer 100. In an embodiment, a first second resin layer (hereinafter, will be referred to as “2-1 resin layer”) (not shown) may be disposed under the 1-1 resin layer 100A, a second second resin layer (hereinafter, will be referred to as “2-2 resin layer”) 100B′ may be disposed under the 1-2 resin layer 100B, a third second resin layer (hereinafter, will be referred to as “2-3 resin layer”) (not shown) may be disposed under the 1-3 resin layer 100C, and a fourth second resin layer (hereinafter, will be referred to as “2-4 resin layer”) (not shown) may be disposed under the 1-4 resin layer 100D.

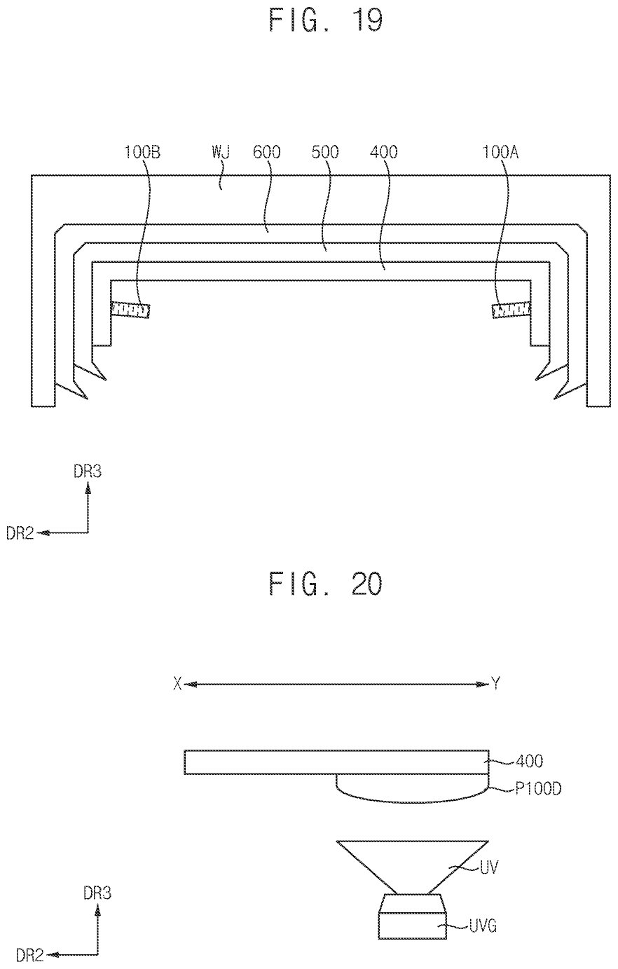

As in a method of manufacturing a display device according to an alternative embodiment of this disclosure which will be described with reference to FIGS. 20 to 24, a part of a guide film (e.g., the guide film GF of FIG. 24) may remain under the first resin layer 100. The 2-2 resin layer 100B′ may mean the same configuration as the remaining part of the guide film.

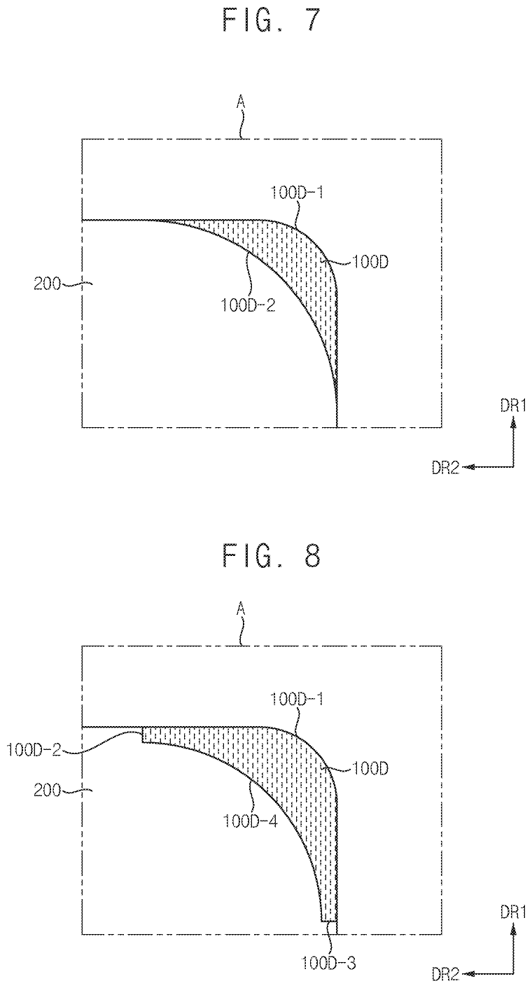

FIGS. 7 to 9 are enlarged views of part A of FIG. 5. The 1-4 resin layer 100D may have a same structure as the remaining resin layers (that is, the 1-1 resin layer 100A, the 1-2 resin layer 100B, and the 1-3 resin layer 100C). The 1-4 resin layer 100D will be described with reference to FIGS. 7 to 9, and any repetitive detailed description of the remaining resin layers will be omitted.

Referring to FIGS. 1 and 7, in an embodiment, the 1-4 resin layer 100D may include a first surface 100D-1 disposed along a portion of an edge of the display device 1000 in a plan view. In addition, the 1-4 resin layer 100D may include a second surface 100D-2 connecting one end of the first surface 100D-1 and the other end of the first surface 100D-1. In an embodiment, the second surface 100D-2 may be a curved surface. That is, the 1-4 resin layer 100D may have a shape surrounded by the first surface 100D-1 and the second surface 100D-2 in a plan view. However, the disclosure is not limited thereto.

In an alternative embodiment, for example, referring to FIGS. 1, 8, and 9, the 1-4 resin layer 100D may include a first surface 100D-1 disposed along a portion of the edge of the display device 1000 in a plan view. In addition, the 1-4 resin layer 100D may include a second surface 100D-2 extending in the first direction DR1. In addition, the 1-4 resin layer 100D may include a third surface 100D-3 extending in the second direction DR2. In addition, the 1-4 resin layer 100D may include a fourth surface 100D-4 connecting the second surface 100D-2 and the third surface 100D-3.

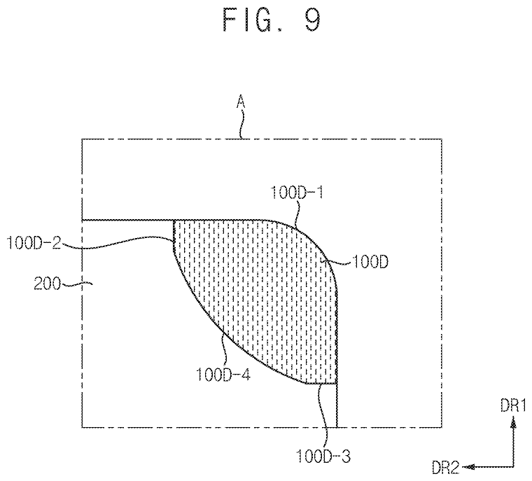

In an embodiment, the fourth surface 100D-4 may be a curved surface. FIG. 8 may show an embodiment where the fourth surface 100D-4 has a convex curved surface toward the first surface 100D-1. FIG. 9 may show an embodiment where the fourth surface 100D-4 has a convex curved surface toward a center of the display device 1000.

The 1-4 resin layer 100D may have a shape surrounded by the first surface 100D-1, the second surface 100D-2, the third surface 100D-3, and the fourth surface 100D-4) in a plan view.

Referring back to FIGS. 1, 3, 5, and 6, as the first resin layer 100 is disposed under the protective film 200, the compressive stress that can act on the display panel 400 may decrease. Specifically, as the first resin layer 100 is disposed under the protective film 200, the compressive stress that can act on the first to fourth panel corner parts 45, 46, 47, and 48 may decrease during the lamination process.

In an embodiment, the greater the curvature amount of the first to fourth panel corner parts 45, 46, 47, and 48, the greater the compressive stress acting on the first to fourth panel corner parts 45, 46, 47, and 48. In such an embodiment, as the first resin layer 100 is disposed under the protective film 200, the compressive stress may be substantially or significantly reduced. Accordingly, buckling or cracks may be prevented from occurring in the corner areas CA1, CA2, CA3, and CA4 of the display device 1000.

FIG. 10 is a perspective view illustrating a guide film according to an embodiment.

Referring to FIG. 10, an embodiment of a guide film GF may include a main area MA and an auxiliary area SA. The auxiliary area SA may extend from the main area MA. The auxiliary area SA may include a plurality of areas. In an embodiment, for example, The auxiliary area SA may include a first auxiliary area SA1 extending from a first side area GN1, a second auxiliary area SA2 extending from a second side area GN2, a third auxiliary area SA3 extending from a third side area GN3, and a fourth auxiliary area SA4 extending from a fourth side area GN4. The plurality of auxiliary areas SA1, SA2, SA3, and SA4 may be spaced apart from each other.

The main area MA may include a central area MAC, a side area GN, and a corner area GC. The central area MAC may correspond to a central portion of the main area MA. The central area MAC may have a rectangular shape including a plane defined by the first direction DR1 and the second direction DR2.

The side area GN may be disposed between the central area MAC and the auxiliary area SA. The side area GN may include a plurality of side areas. In an embodiment, for example, the side area GN may include the first side area GN1 disposed between the central area MAC and the first auxiliary area SA1, the second side area GN2 disposed between the central area MAC and the second auxiliary area SA2, the third side area GN3 disposed between the central area MAC and the third auxiliary area SA3, and the fourth side area GN4 disposed between the central area MAC and the fourth auxiliary area SA4.

The corner area GC may be located at a corner of the main area MA. The corner area GC may include a plurality of corner areas. In an embodiment, for example, the corner area GC may include a first corner area GC1 connecting (or between) the first side area GN1 and the fourth side area GN4, a second corner area GC2 connecting the first side area GN1 and the second side area GN2, a third corner area GC3 connecting the second side area GN2 and the third side area GN3, and a fourth corner area GC4 connecting the third side area GN3 and the fourth side area GN4.

Each of the plurality of corner areas GC1, GC2, GC3, and GC4 may include a cutout portion. That is, each of the plurality of corner areas GC1, GC2, GC3, and GC4 may include an empty space in which the guide film GF does not exist. As will be described with reference to FIGS. 11 to 19, a first resin layer (for example, the first resin layer 100 of FIG. 5) may be disposed in the cutout portion.

In an embodiment, the guide film GF may include a resin film. The resin film may include polyethylene terephthalate (“PET”), polymethyl methacrylate (“PMMA”), polyurethane (“PU”), polycarbonate (“PC”), or the like. These materials may be used alone or in combination with each other. However, the disclosure is not limited thereto, and the resin film may include other kinds of materials.

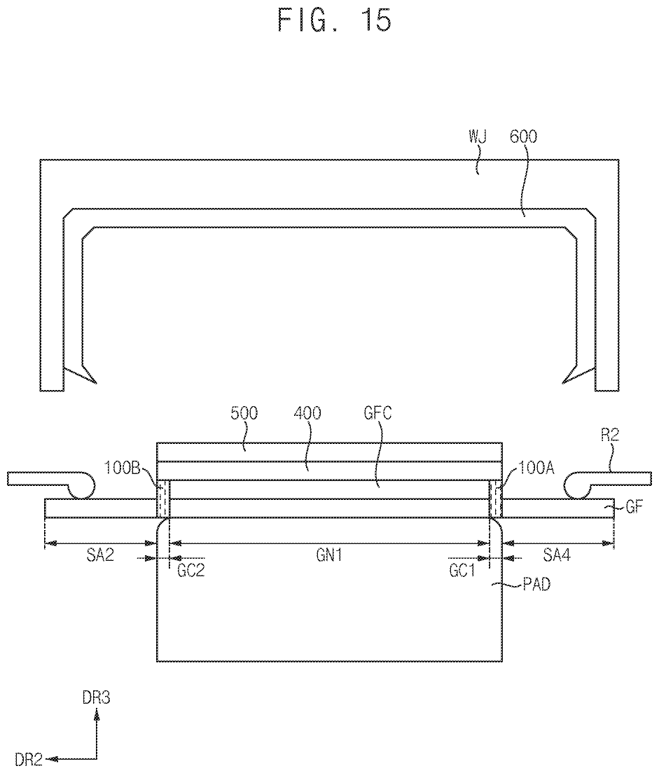

FIGS. 11 to 19 are views illustrating a method of manufacturing a display device according to an embodiment. Specifically, FIGS. 12 to 14 are views illustrating portions overlapping line X-Y of FIG. 11 of the display device. In addition, FIGS. 15 to 19 are front views illustrating an embodiment of the method of manufacturing the display device.

In FIGS. 2 and 6, an embodiment in which the first resin layer 100 is disposed under the protective film 200 is shown. For convenience of illustration and description, in FIGS. 11 to 19 showing the method of manufacturing the display device according to an embodiment, the first resin layer 100 is placed under the display panel 400.

Referring to FIGS. 11 and 12, a guide film GF may be attached to a rear surface of the display panel 400. in an embodiment, an film adhesion layer GFC may be attached to a back of the display panel 400, and then the guide film GF may be attached to a back of the film adhesion layer GFC. The film adhesion layer GFC may provide an adhesive force to the display panel 400.

In an embodiment, the film adhesion layer GFC may include an OCA, an OCR, or a PSA. However, the disclosure is not limited thereto, and the film adhesion layer GFC may include other kinds of materials.

The film adhesion layer GFC may include a first adhesion layer corner area GC1′ overlapping the first corner area GC1 of the guide film GF, the second adhesion layer corner area GC2′ overlapping the second corner area GC2 of the guide film GF, a third adhesion layer corner area GC3′ overlapping the third corner area GC3 of the guide film GF, and a fourth adhesion layer corner area GC4′ overlapping the fourth corner area GC4 of the guide film GF.

Each of the first to fourth adhesion layer corner areas GC1′, GC2′, GC3′, and GC4′ may include a cutout portion. That is, each of the first to fourth adhesion layer corner areas GC1′, GC2′, GC3′, and GC4′ may define an empty space in which the film adhesion layer GFC does not exist. The first resin layer (e.g., the first resin layer 100 of FIG. 5) may be disposed in the empty space.

In an embodiment, as shown in FIG. 11, the guide film GF may be attached to the rear surface of the display panel 400 through the film adhesion layer GFC. In an embodiment, the panel front part 40 may be disposed corresponding to the central area MAC of the guide film GF.

Referring further to FIG. 3, the first panel side part 41 may be disposed corresponding to the first side area GN1 of the guide film GF. In addition, the second panel side part 42 may be disposed corresponding to the second side area GN2 of the guide film GF. In addition, the third panel side part 43 may be disposed corresponding to the third side area GN3 of the guide film GF. In addition, the fourth panel side part 44 may be disposed corresponding to the fourth side area GN4 of the guide film GF.

In addition, the first panel corner part 45 may be disposed corresponding to the first corner area GC1 of the guide film GF. In addition, the second panel corner part 46 may be disposed corresponding to the second corner area GC2 of the guide film GF. In addition, the third panel corner part 47 may be disposed corresponding to the third corner area GC3 of the guide film GF. In addition, the fourth panel corner part 48 may be disposed corresponding to the fourth corner area GC4 of the guide film GF.

In an embodiment, as shown in FIG. 11, when the guide film GF is attached to the rear surface of the display panel 400, a first roller R1 may be used. The first roller R1 may move in a direction opposite to the first direction DR1 (e.g., a direction from the third panel side part 43 to the first panel side part 41) and pressure the display panel 400 and the guide film GF for the guide film GF to attach well to the back surface of the display panel 400.

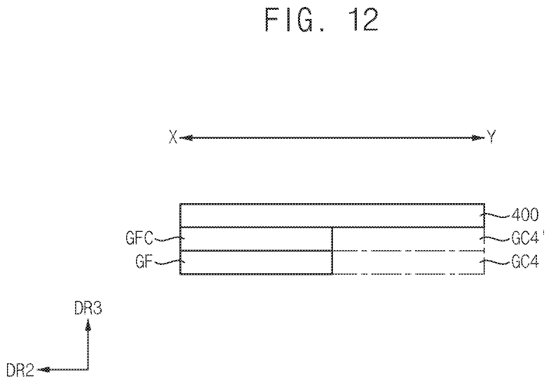

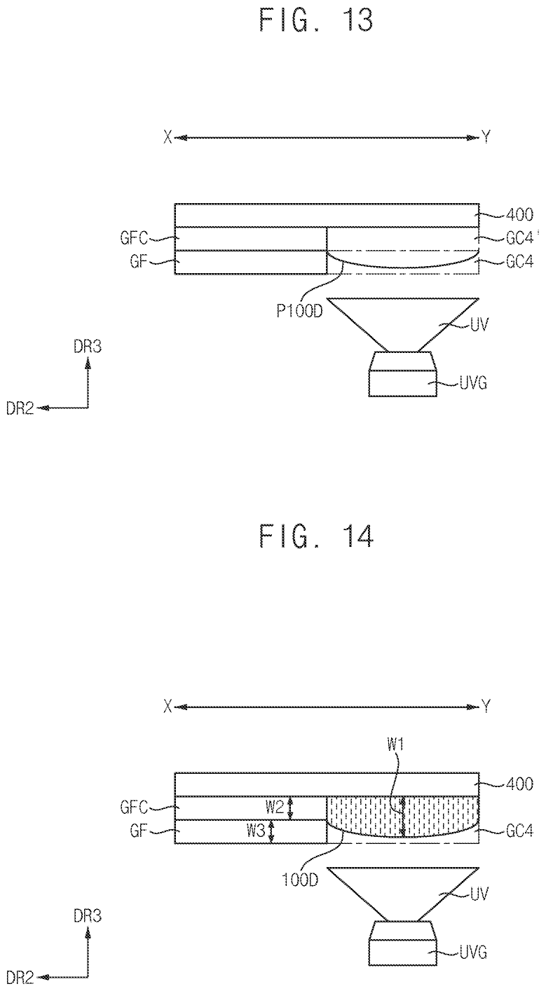

Referring to FIGS. 13 and 14, a 1-4 preliminary resin layer P100D may be applied to the back of the display panel 400 exposed by the fourth corner area GC4 of the guide film GF and the fourth adhesion layer corner area GC4′ of the film adhesion layer GFC. In an embodiment, the 1-4 preliminary resin layer P100D may be applied by a dispenser.

The 1-4 preliminary resin layer P100D may be cured by a light irradiation unit UVG. In an embodiment, the light irradiation unit UVG may emit light UV to the 1-4 preliminary resin layer P100D. Accordingly, the 1-4 preliminary resin layer P100D may be cured to form the 1-4 resin layer 100D. In an embodiment, the light UV may be a light emitting diode (“LED”), for example, an ultraviolet (“UV”) LED. In an embodiment, the light UV may have a wavelength in a range of about 320 nanometers (nm) to about 400 nm.

A thickness W1 of a central portion of the 1-4 resin layer 100D may be less than the sum of a thickness W2 of the film adhesion layer GFC and a thickness W3 of the guide film GF. If the thickness W1 of the central portion of the 1-4 resin layer 100D is greater than the sum of the thickness W2 of the film adhesion layer GFC and the thickness W3 of the guide film GF, the 1-4 resin layer 100D may overflow to a lower surface of the guide film GF.

Referring to FIGS. 12 to 14, a process of forming the 1-4 resin layer 100D is described, but the remaining resin layers 100A, 100B, and 100C may also be formed through a same process as the process of forming the 1-4 resin layer 100D and may have a same structure as the 1-4 resin layer 100D.

Referring to FIG. 15, a cover window 600 may be prepared. A stage in which the cover window 600 is prepared may be a stage in which the cover window 600 is deformed to have a curve using a jig WJ including a curved part. The jig WJ may correspond to a frame having a shape corresponding to a shape of the display device (e.g., the display device 1000 of FIG. 1) to be manufactured. The cover window 600 is closely attached to the inside (or an inner surface) of the jig WJ so that the cover window 600 may be deformed according to the shape of the inside of the jig WJ.

A second adhesive layer 500 may be disposed on the display panel 400. The second adhesive layer 500 may provide an adhesive force to the cover window 600 so that the display panel 400 is attached to the cover window 600.

A pad part PAD may be disposed on a rear surface of the guide film GF, that is, the guide film GF may be seated on the pad part PAD. In addition, a second roller R2 may be disposed on the guide film GF.

Referring to FIG. 16, top surfaces of the display panel 400 and the second adhesive layer 500 may be bonded to the cover window 600 using the pad part PAD. In this case, the second roller R2 may press the guide film GF in a direction opposite to the third direction DR3 such that the guide film GF is bent in a shape corresponding to a shape of an upper portion of the pad part PAD.

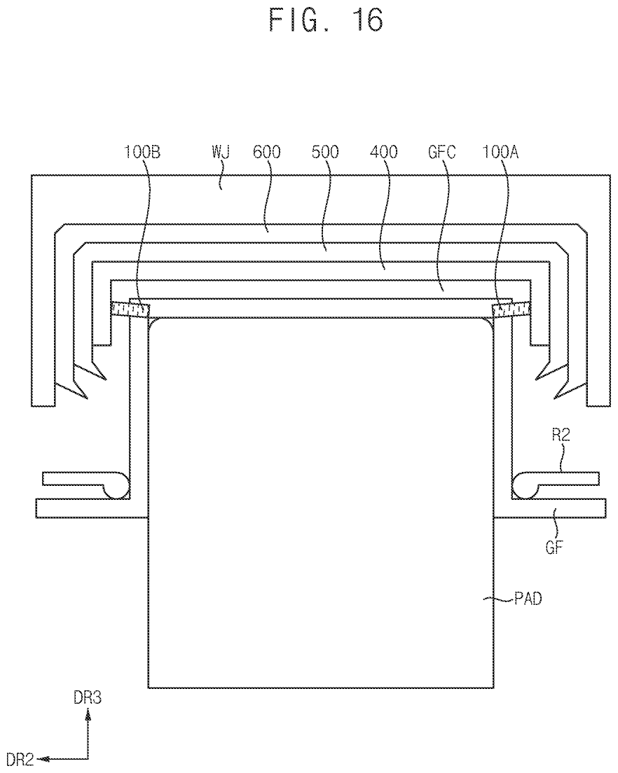

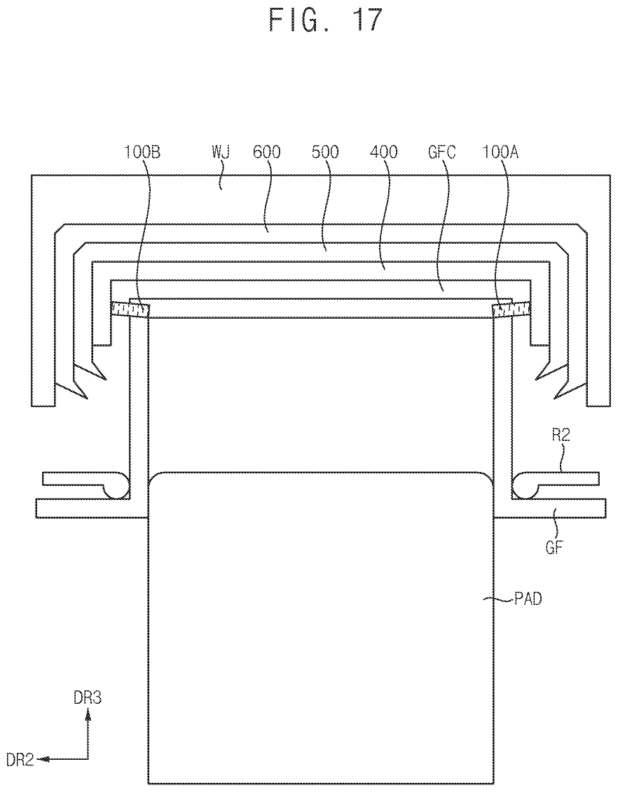

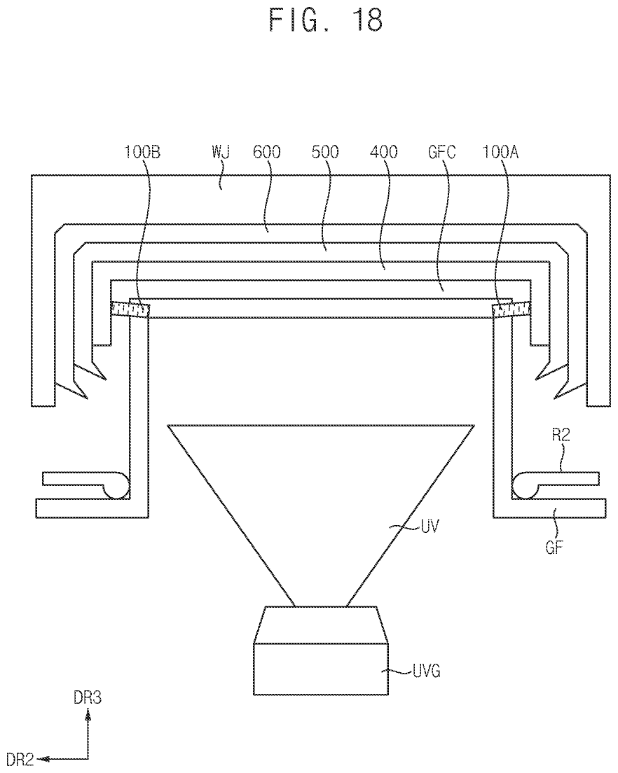

Referring to FIGS. 17 and 18, after the pad part PAD is removed, the light irradiation unit UVG may radiate light UV onto the guide film GF. Accordingly, the guide film GF is cured, and the adhesive force of the guide film GF may be removed. Accordingly, as shown in FIG. 19, the guide film GF may be removed from the rear surface of the display panel 400.

FIGS. 20 to 24 are views illustrating a method of manufacturing a display device according to an alternative embodiment. Specifically, FIGS. 20 to 24 are views illustrating a portion overlapping line X-Y of FIG. 11 of the display device.

In describing a method of manufacturing the display device according to an alternative embodiment with reference to FIGS. 20 to 24, any repetitive detailed description of substantially the same process as that of the method of manufacturing the display device according to an embodiment described with reference to FIGS. 12 to 19 may be omitted.

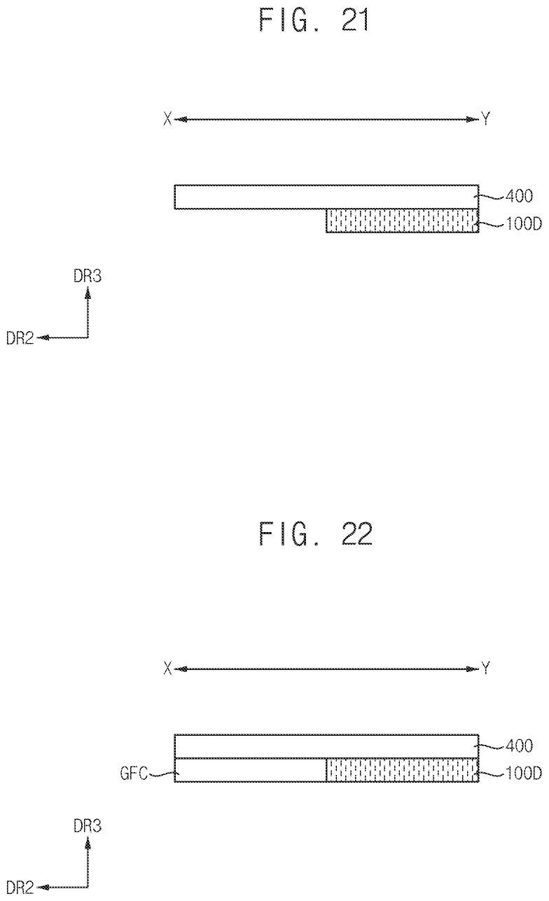

Referring to FIGS. 20 and 21, a preliminary 1-4 resin layer P100D may be applied to a rear surface of the display panel 400. Thereafter, the 1-4 preliminary resin layer P100D may be cured by a light irradiation unit UVG. In an embodiment, the light irradiation unit UVG may emit light UV to the 1-4 preliminary resin layer P100D. Accordingly, the 1-4 preliminary resin layer P100D may be cured to form the 1-4 resin layer 100D.

Referring to FIG. 22, a film adhesive layer GFC may be disposed on a portion of the rear surface of the display panel 400 to which the 1-4 resin layer 100D is not applied.

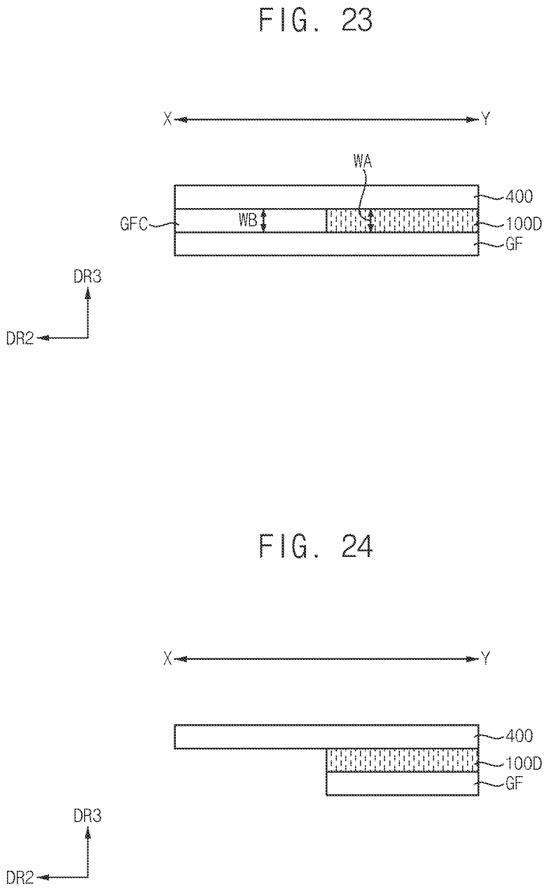

Referring to FIG. 23, a guide film GF may be disposed on rear surfaces of the 1-4 resin layer 100D and the film adhesion layer GFC. In an embodiment, a thickness WA of the 1-4 resin layer 100D may be less than or equal to a thickness WB of the film adhesion layer GFC such that the guide film GF may be arranged in parallel with the display panel 400.

Thereafter, the guide film GF and the film adhesion layer GFC may be removed through the processes of FIGS. 16 to 19. In such an embodiment, a portion of the guide film GF disposed under the 1-4 resin layer 100D may not be removed.

That is, referring to FIG. 24, due to the adhesion of the 1-4 resin layer 100D, the portion of the guide film GF except for the portion of the guide film GF overlapping the 1-4 resin layer 100D may be removed. The remaining portion of the guide film GF may include a same material as the 2-2 resin layer 100B′ of FIG. 6.

Referring to FIGS. 20 to 24, a process of forming a portion overlapping the fourth corner area (e.g., the fourth corner area CA4 of FIG. 1) of the display device (e.g., the display device 1000 of FIG. 1) is described, but the remaining corner areas (e.g., the first to third corner areas CA1, CA2, and CA3, of FIG. 1) may be formed with a same process as and have a same structure as those described above.

Embodiments of the disclosure can be applied to various display devices, such as display devices for vehicles, ships and aircraft, portable communication devices, display devices for exhibition or information transmission, medical display devices, or the like, for example.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel including a front area, side areas disposed around the front area, and corner areas respectively disposed between two adjacent side areas among the side areas, wherein the display panel includes a flat surface in the front area and a curved surface in the side areas and the corner areas; and
a first resin layer disposed under the display panel and partially overlapping the corner areas.

2. The display device of claim 1, wherein the first resin layer includes a first surface disposed along a portion of an edge of the display device in a plan view.

3. The display device of claim 2, wherein the first resin layer has a shape surrounded by the first surface, a second surface extending from the first surface in a first direction, a third surface extending from the first surface in a second direction crossing the first direction, and a fourth surface connecting the second surface and the third surface in a plan view.

4. The display device of claim 3, wherein the fourth surface is a curved surface.

5. The display device of claim 1, further comprising:
a second resin layer disposed under the first resin layer.

6. The display device of claim 1, further comprising:
a protective film disposed between the first resin layer and the display panel.

7. The display device of claim 6, further comprising:
a first adhesive layer disposed between the display panel and the protective film.

8. The display device of claim 1, further comprising:
a second adhesive layer disposed on the display panel; and
a cover window disposed on the second adhesive layer.

9. The display device of claim 1, wherein the first resin layer has a modulus of about 0.2 MPa or greater and about 1 GPa or less.

10. The display device of claim 1, wherein the first resin layer has a viscosity of about 300 cps or greater and about 1,000,000 cps or less.

11. The display device of claim 1, wherein a thickness of the first resin layer is about μm or greater and about 500 μm or less.

12. A method of manufacturing a display device, the method comprising:
preparing a display panel including a front area, side areas disposed around the front area, and corner areas respectively disposed between two adjacent side areas among the side areas;
attaching a guide film, in which a first cutout portion partially overlapping the corner areas is defined, to a rear surface of the display panel;
providing a resin layer on a portion of a rear surface of the display panel exposed by the first cutout portion;
disposing a cover window on a front surface of the display panel; and
removing the guide film.

13. The method of claim 12, wherein the attaching the guide film to the rear surface of the display panel includes:
providing an adhesive layer, in which a second cutout portion overlapping the first cutout portion is defined, on the rear surface of the display panel; and
attaching the guide film to a rear surface of the adhesive layer.

14. The method of claim 13, wherein a thickness of the resin layer is less than or equal to a sum of a thickness of the adhesive layer and a thickness of the guide film.

15. The method of claim 12, wherein the providing the resin layer on the portion of the rear surface of the display panel exposed by the first cutout portion includes:
applying a preliminary resin layer on the portion of the rear surface of the display panel exposed by the first cutout portion; and
curing the preliminary resin layer.

16. A method of manufacturing a display device, the method comprising:
preparing a display panel including a front area, side areas disposed around the front area, and corner areas respectively disposed between two adjacent side areas among the side areas;
providing a resin layer partially overlapping the corner areas on a rear surface of the display panel;
attaching a guide film to a rear surface of the resin layer;
disposing a cover window on a front surface of the display panel; and
removing the guide film.

17. The method of claim 16, wherein the providing the resin layer on the rear surface of the display panel includes:
applying a preliminary resin layer on the rear surface of the display panel; and
curing the preliminary resin layer.

18. The method of claim 16, wherein the attaching the guide film to the rear surface of the resin layer includes:
providing an adhesive layer on the rear surface of the display panel except for an area where the resin layer is provided; and
attaching the guide film on the rear surface of the adhesive layer and the resin layer.

19. The method of claim 18, wherein a thickness of the resin layer is less than or equal to a thickness of the adhesive layer.

20. The method of claim 19, wherein the removing the guide film comprises removing the guide film except for a portion thereof overlapping the resin layer.
